(19) United States
(12) Patent Application Publication
(10) Pub. No.: US 2014/0230899 A1
(43) Pub. Date: Aug. 21, 2014

(54) MODULE AND METHOD FOR PRODUCING THEREOF

(71) Applicant: LISEC AUSTRIA GmbH, Seitenstetten (AT)

(72) Inventors: Vesselinka Petrova-Koch, Garching (DE); Andreas Mader, Neuhofen/Ybbs (AT); Markus Jandl, Viehdorf (AT); Ralf Bohlander, Erkrath (DE)

(73) Assignee: LISEC AUSTRIA GmbH, Seitenstetten (AT)

(21) Appl. No.: 14/346,484

(22) PCT Filed: Sep. 24, 2012
(86) PCT No.: PCT/AT2012/000242

§ 371 Date: Mar. 21, 2014

(30) Foreign Application Priority Data
Sep. 22, 2011 (AT) A 1370/2011

(51) Int. Cl. H01L 31/048; H01L 31/18

(52) U.S. Cl. CPC H01L 31/0488; H01L 31/18
USPC 136/259; 438/66

(57) ABSTRACT

A module, for example a photovoltaic module, includes among other things a glass plate (11) as a front cover facing the direction of light incidence, a component (photovoltaic element) (15), and a plastic layer (14) provided as an embedding material, wherein the surface of the glass plate (11) on the side facing the plastic layer (14) is treated such that the index of refraction of the layer produced by the surface treatment has a value between the index of refraction of the glass of the cover (11) and the index of refraction of the plastic material of the layer (14).

The invention relates to a module that consists of at least one layer of surface-treated glass and at least one layer of plastic.

A module, in which plastic is present as a film material, can be produced in a lamination method.

Within the framework of the invention, consideration is given to, i.a., vacuum modules or glass-glass modules, as are used in photovoltaics, organic light-emitting diodes (OLED), shading elements, illuminating elements, and laminated glass. In particular, the invention relates to a photovoltaic module (=solar module).

Photovoltaic modules usually consist of at least one photovoltaic element (=solar cell), which is encapsulated between cover plates. At least the cover plate that faces toward the incident light is translucent. It is also known to provide a plastic layer, e.g., in the form of a film, between the photovoltaic element and the cover plate that faces toward the incident light in order to encapsulate the photovoltaic element.

The design of a typical solar module can be described as follows:
A glass pane (in most cases, so-called tempered safety glass, in short TSG) as a front-side cover on the side facing the sun.
A transparent plastic layer (ethylene vinyl acetate (EVA), polyvinyl butyral (PVB) or silicones or silicone resin), in which the solar cells are embedded,
Monocrystalline or polycrystalline solar cells (photovoltaic elements), which are electrically connected to each other by strips of solder,
Lamination or covering on the back side with a weather-resistant plastic composite film, e.g., made of polyvinyl fluoride (Tedlar) or polyester,
Receptacle with free-wheeling diode or bypass diode and connecting terminal,
An aluminum profile frame for protecting the glass pane during shipping, handling and assembly, for reinforcement, and for strengthening the bond.

It is problematic in known modules of the above-mentioned type, in particular in photovoltaic modules, that light (sunlight) that strikes against the module reaches the embedded photovoltaic cells with considerable losses, such that the efficiency of photovoltaic modules is lower than that of the photovoltaic cells themselves.

In addition, ionic contaminants, such as, e.g., sodium ions, can diffuse from the soda-lime glass through the embedding films to the photovoltaic cells, by which the electrical behavior of the modules can also be impaired.

The object of the invention is to indicate a module of the above-mentioned type, which is designed simply and comprises the enhanced mechanical, physical-chemical, and/or optical properties by interface matching (“matching”). In particular, the module according to the invention, when it is a photovoltaic module, is to have a high efficiency.

This object is achieved according to the invention with a module that has the features of Claim 1.

Preferred and advantageous configurations of the module according to the invention are subjects of the subclaims.

In particular, the module according to the invention, even when it is a photovoltaic module, has an enhanced adhesion between glass and plastic, in particular the casting resin or the lamination film. This is also the case with customary functionalized laminated glass or vacuum elements.

In addition, in the module according to the invention, it is advantageous that in a preferred embodiment, a reduced transfer of sodium ions from the glass into the plastic, in particular the plastic film, takes place. This is advantageous since it prevents sodium ions from damaging the semiconductor components (of photovoltaic elements).

Finally, the module according to the invention has the advantage of an increased transmission of light, since the relative indices of refraction are adjusted.

When the module according to the invention is a photovoltaic module, it is ensured to a very large extent that incident light reaches the (at least one) photovoltaic element and light is converted with high efficiency into electricity.

These measures are in particular:
With use of a cover that is made of glass, in particular low-iron soda-lime glass—with its outer surface, the one facing away from the photovoltaic element, i.e., facing the incident light—light reflection is treated in such a way as to reduce it,
The use of a cover that is made of translucent material, e.g., glass, in particular soda-lime glass, whose optical properties are adjusted by surface treatment so that the layer that is formed by the surface treatment has an index of refraction that has a value between the index of refraction of the glass and the index of refraction of the plastic.

Modules according to the invention, in particular also photovoltaic modules according to the invention, can be produced by vacuum encapsulation or by customary lamination methods when the additional method steps of the surface treatment, in particular treatment with water glass, are taken into consideration.

In the method according to the invention for treating glass (with the purpose of changing its optical properties and hardening it), for example, the following method steps can be implemented:

### 1. Pre-Cleaning/Activation

The surface of the glass is (again) made fresh in order to remove oils, fats and solid particles, e.g., cutting oil on the edge of the pane. For a successful treatment with a potassium-water glass solution, it is advantageous that the solution wets the glass, i.e., a through-going film, and no drops/streaks are formed, i.e., potassium-water glass solution is uniformly applied on the surface of the glass that is to be treated.

It is advantageous when the time span between the pre-cleaning/activation and the actual treatment is as short as possible, so that the surface of the glass is not further contaminated, e.g., by dust.

2. Spraying with Treatment Means

For example, soda-lime plate glass is sprayed with an aqueous potassium-water glass solution, which is applied, for example, on the plate glass that is essentially oriented in a perpendicular manner by a vertical spraying bar according to the sol-gel method. Sol-gel method is defined here as a method in which a sol that is applied on the glass is then converted into a gel by removing (evaporating) the solvent (water).

It is not so very essential in this case to atomize the solution that consists of potassium-water glass that is to be applied, but rather to ensure that a closed surface (film) of the sol on the glass surface is produced, which is achieved in particular by the pretreatment mentioned in the item above.

### 3. Reaction Time (Drying)

The applied sol is allowed to dry to form a gel, which also can take place without a climatic chamber or special clean room conditions. In this case, the potassium-water glass reacts with the glass, in particular the soda-lime glass.

Depending on the climatic ratios and pane temperature, the drying time is between 5 minutes and 25 minutes.

The drying time can be accelerated by a(n) (slightly) elevated temperature of the plate glass and/or heat panels and/or (slight) convection with dry air.

It is advantageous when the sol dries completely to form gel, since otherwise the danger exists that large components of the layer are removed, and spots are visible in the surface of the (plate) glass.

A good treatment of the surface is indicated when a bluish-violet gleam can be seen in the daylight.

### 4. Subsequent Cleaning

The purpose is that with a large volume of tempered osmosis water (conductivity of less than 30 μS/cm), unbonded potassium is dissolved from the layer.

5. The layer is compressed and the bond with the glass substrate is

strengthened by thermal hardening of the treated glass.

Another possibility considered within the framework of the invention consists in adding additives to the potassium-water glass to change the properties of glass according to the treatment according to the invention. Such additives can be dyes, e.g., a white dye (such as zinc oxide) that enhances the reflection behavior, a substance producing fluorescence, or a substance that makes the layer that is obtained after the treatment and that is present in the surface of the glass electrically conductive.

Below, embodiments of the invention are reproduced.

### EXAMPLE 1

In this example, clear glass that is 2.1 mm thick and with dimensions of 550×360 mm is provided with a surface that has a reduced reflection.

The procedure is as follows:

The glass is washed in the washing machine with hot water that is approximately 40° C. Subsequently, the glass surface is treated with a butane gas flame. Then, a glass surface is sprayed with an aqueous potassium-water glass solution. After this, there is a waiting period until the potassium-water glass has reacted with the glass in the area of its surface, which takes approximately 10 to 15 minutes.

The solution that was used for spraying had the following composition of 96-97% by weight of water and 3-4% by weight of proportions of solids (SiO₂, K₂O, . . . ), whereby the potassium content of the liquid is less than 1% by weight, and a proportion of solid of 3.4% by weight is present in the treatment material.

Subsequently, the glass is flushed again with hot water of 40° C.

Subsequently, the glass is subjected to thermal hardening, whereby a non-contact procedure is carried out.

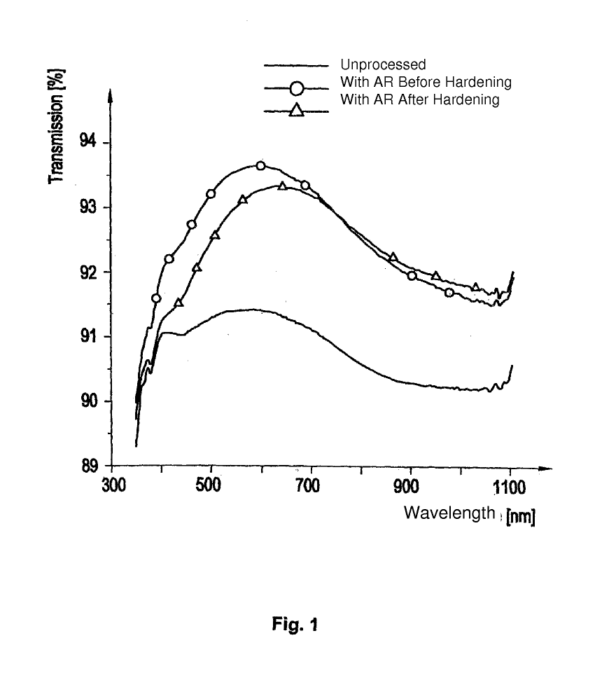

As a result, the permeability levels (transmissions) are achieved, which are shown in the diagram of FIG. 1.

### EXAMPLE 2

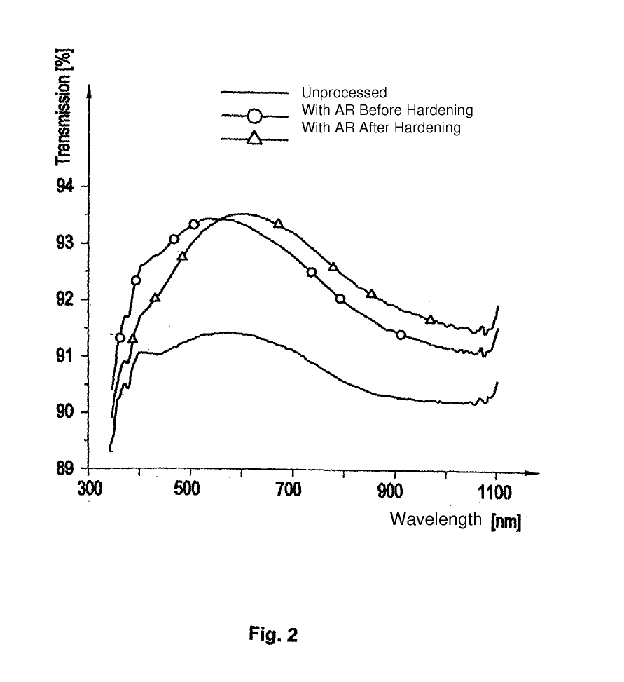

With the mode of operation indicated in Example 1 and with use of the means mentioned there, three pieces of glass panes are treated on one side with potassium-water glass and hardened. In this test, the transmission values reproduced in the diagram of FIG. 2 (the curves are mean values over the three panes) are determined.

### EXAMPLE 3

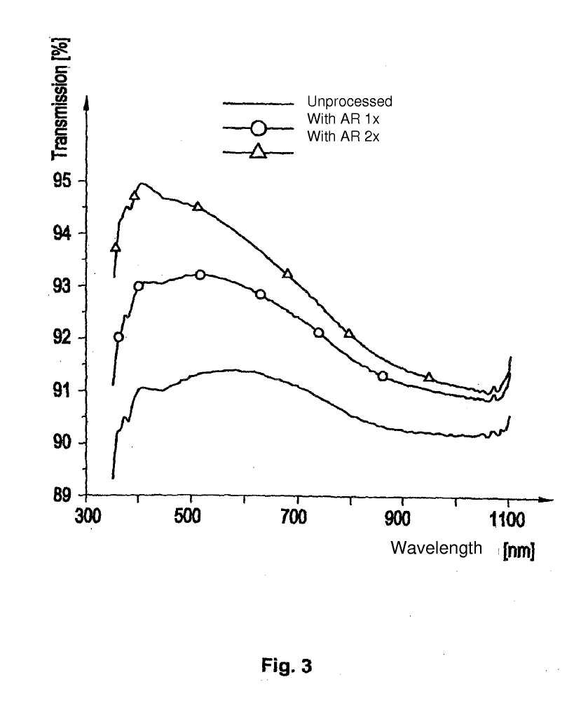

Glass panes are treated with the mode of operation and the means that are mentioned in Example 1. In one pane, one-third of the surface is left untreated, one-third of the surface is treated on one side, and one-third of the surface is treated on both sides, whereby the treatment is carried out according to the mode of operation and with the means that are mentioned in Example 1. In this test, the transmission values according to FIG. 3 are achieved.

The treatment of the surface of glass that is provided in a possible embodiment of the invention can comprise, for example, the following method steps:
The object that is made of glass, preferably a plate glass pane, in particular a plate glass pane that is made of soda-lime glass, is cleaned,
An aqueous solution of potassium-water glass is applied in a continuous layer to the object by the object that is made of glass being sprayed with an aqueous solution of potassium-water glass,
The layer that is applied on the object that is made of glass is allowed to dry, whereby the potassium-water glass reacts with the surface of the object that is made of glass,
Unbonded potassium is washed out from the applied layer with water, and
The object that is made of glass is heated for heat treatment and cooled again to room temperature for thermal hardening.

In the surface treatment of the object that is made of glass, it can be provided that the object is heated for heat treatment to a temperature in the range of 600 to 650° C., preferably without contact, and then it is cooled again to room temperature.

In the surface treatment of the object that is made of glass, it can be provided that a solution is used that in water contains 3 to 4% by weight, preferably 3.4% by weight, of solids of the potassium-water glass.

In the surface treatment of the object that is made of glass, it can be provided that a solution is used that contains less than 2% by weight, in particular less than 1% by weight, of potassium.

In the surface treatment of the object that is made of glass, it can be provided that a solution is used to which at least a dye, in particular a mineral dye, is added.

In the surface treatment of the object that is made of glass, it can be provided that a solution is used to which at least one substance that triggers fluorescence is added.

In the surface treatment of the object that is made of glass, it can be provided that a solution is used to which at least one substance that ensures conductivity is added.

In the surface treatment of the object that is made of glass, it can be provided that the object is treated with an open flame after cleaning and before the layer is applied.

In the surface treatment of the object that is made of glass, it can be provided that during cleaning and/or during the washing-out of potassium, it is washed with hot water that is approximately 30 to 50° C., in particular 40° C.

In the surface treatment of the object that is made of glass, it can be provided that water that is regenerated for washing out unbonded potassium, in particular water with a conductivity of less than 50 μS/cm, preferably less than 30 μS/cm, is used.

In the surface treatment of the object that is made of glass, it can be provided that before spraying with the solution of potassium-water glass, the object is heated to a temperature of between 20 and 40° C., preferably to approximately 30° C.

In the surface treatment of the object that is made of glass, it can be provided that when plate glass is being treated, the latter is treated essentially oriented vertically.

In the surface treatment of the object that is made of glass, it can be provided that the solution that contains potassium-water glass is sprayed on the plate glass from nozzles that are arranged vertically above one another.

In the surface treatment of the object that is made of glass, it can be provided that the object that is made of glass is treated on one side.

In the surface treatment of the object that is made of glass, it can be provided that the object that is made of glass is treated on both sides.

In the surface treatment of the object that is made of glass, it can be provided that the treatment of the object that is made of glass, implemented with potassium-water glass, and subsequent heating result in the formation of a nanoporous skin on the surface of the glass object.

In the surface treatment of the object that is made of glass, it can be provided that in this case, the object that is made of glass is heated to a temperature on the order of 600° C. to 650° C.

In the surface treatment of the object that is made of glass, it can be provided that after the object that is made of glass and that is present as plate glass is heated, it is abruptly cooled in order to harden the plate glass.

In the surface treatment of the object that is made of glass, it can be provided that potassium that is not bonded to the object is washed out from the nanoporous surface.

Within the framework of the invention, the variants of the modules that are cited below are considered:

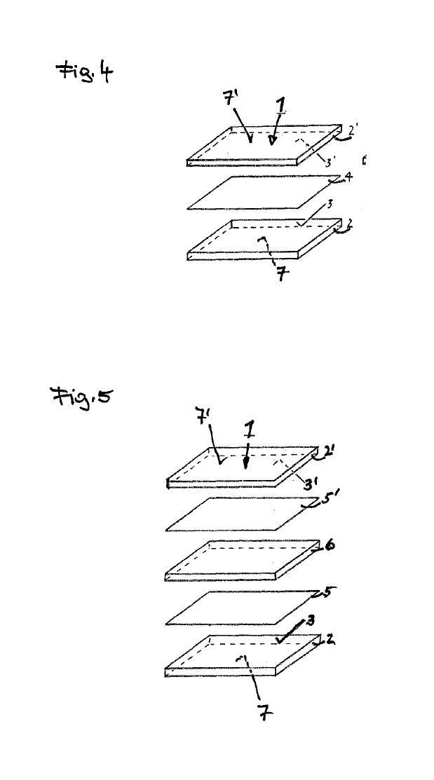

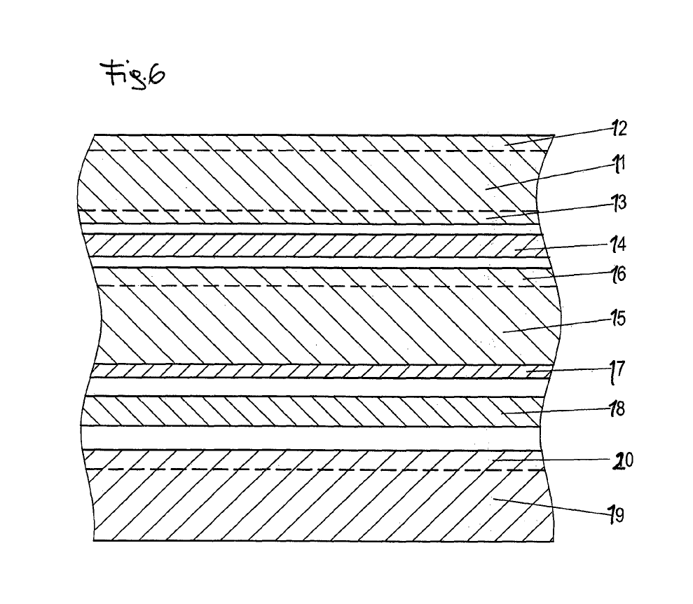

The modules 1 that are shown diagrammatically in FIG. 4 and FIG. 5 in an exploded depiction consist of two flat or plate-like components 2, 2′ that are arranged in a plane-parallel manner, of which at least the first component 2 is designed as a plate glass pane and is introduced between the one film 4 (FIG. 4) or a plate-like or film-like component 6 embedded between two films 5, 5′ (FIG. 5). The components 2, 2′ as well as the film 4 that is introduced in-between or the stack that is made of the two films 5, 5′ that is introduced in-between and the component 6 that is located between the latter are connected to one another by lamination, whereby before the assembly of the module, the film-side surface 3 is subjected to a surface treatment (in particular as described above), or, if both components 2, 2′ are designed as plate glass panes, optionally also a surface treatment is performed on both film-side surfaces 3, 3′.

As an alternative, before the assembly of the module 1, the film-side surface 3 is subjected to a surface treatment (in particular as described above), or, if both components 2, 2′ are designed as plate glass panes, optionally also both film-side surfaces 3, 3′ are subjected to a surface treatment (in particular as described above), so that during the course of the lamination process, the film material does not directly go into a connection with the glass but rather with the layer formed on the surface 3 or the layers formed on the surfaces 3, 3′ by the surface treatment.

As an alternative, before the assembly of the module 1, the film-side surface 3 is subjected to a surface treatment (in particular as described above), or, if both components 2, 2′ are designed as plate glass panes, optionally also both film-side surfaces 3, 3′ are subjected to a surface treatment (in particular as described above), by which at least one of the following properties is achieved:
Enhanced adhesion between plate glass pane or panes and film material,
Reduced transfer of sodium ions from the glass into the film material, and
Increased transmission of light in the visible spectral range by the at least one plate glass pane by adjusting the relative index of refraction.

In another alternative, before the assembly of the module 1, the film-side surface 3 is subjected to a surface treatment or, if both components 2, 2′ are designed as plate glass panes, optionally also both film-side surfaces 3, 3′ are subjected to a surface treatment with water glass, whereby the surface treatment comprises the following method steps:
The surfaces 3, 3′, in particular the surfaces of plate glass panes, in particular plate glass panes that are made of soda-lime glass, are cleaned,
An aqueous solution of potassium-water glass is applied in a continuous layer on the components 2, 2′, by the components 2, 2′ being sprayed with an aqueous solution of potassium-water glass,
The layer that is applied on the components 2, 2′ is allowed to dry, whereby the potassium-water glass reacts with the surface of the object,
Unbonded potassium is washed out from the layer with water, and
The components 2, 2′ are heated for heat treatment and cooled again to room temperature for thermal hardening.

In one embodiment of the invention, it can be provided that the treatment of the surface, carried out before assembly, is performed with water glass.

In one embodiment of the invention, it can be provided that the treatment of the surface, carried out before assembly, is performed with potassium-water glass.

In one embodiment of the invention, it can be provided that before assembly, a treatment of the surface with potassium-water glass is carried out according to the following method steps:
The component 2 or 2′, preferably a plate glass pane, in particular a plate glass pane that is made of soda-lime glass, is cleaned,
An aqueous solution of potassium-water glass is applied on the component 2 or 2′ in a continuous layer, by the component 2 or 2′ being sprayed with an aqueous solution of potassium-water glass,
The layer that is applied on the component 2 or 2′ is allowed to dry, whereby the potassium-water glass reacts with the surface of the object,
Unbonded potassium is washed out from the applied layer with water, and
The component 2 or 2′ is heated for heat treatment and cooled again to room temperature for thermal hardening.

In one embodiment of the invention, it can be provided that the index of refraction of the layer that is formed by the surface treatment on the surface 3 and/or 3′ has a value between the index of refraction of the plate glass pane 2 and the film 4 or the films 5 and/or 5′.

In one embodiment of the invention, it can be provided that in the treatment of the surface 3 and/or 3′ before assembly, a solution is used to which at least a dye, in particular inorganic dye, is added.

In one embodiment of the invention, it can be provided that in the treatment of the surface 3 and/or 3′ before assembly, a solution is used to which at least one fluorescent substance is added.

In one embodiment of the invention, it can be provided that in the treatment of the surface 3 and/or 3′ before assembly, a solution is used to which at least one substance that ensures conductivity is added.

In one embodiment of the invention, it can be provided that in which for the treatment of the surface 3′ (pointing upward in FIGS. 4 and 5) of the rear cover before assembly, a solution is used to which a dye is added and that imparts enhanced reflection behavior to the rear cover plate.

In one embodiment of the invention, it can be provided that the incident-light-side surface 7 (pointing downward in FIGS. 4 and 5) of the front cover plate has reduced reflection properties in the wavelength range of visible light.

In one embodiment of the invention, it can be provided that the incident-light-side surface 7 and/or the surface 3 of the front cover plate that faces the laminating film has enhanced reflection behavior for infrared light.

In one embodiment of the invention, it can be provided that the film 4 consists of silicone-based plastic, or optionally both films 5, 5′ consist of silicone-based plastic.

In one embodiment of the invention, it can be provided that the module is designed as a photovoltaic module by incorporating a photovoltaic element as a component 6, and in which the plate-like component 2 that faces the sun, which component serves as a front cover plate, consists of a plate glass pane, while the component 2′ that is turned away from the sun, which serves as a rear cover plate, consists of a material that is different from glass, in particular a metal material or plastic.

In one embodiment of the invention, it can be provided that it is designed as a photovoltaic module by incorporating a photovoltaic element as a component 6 and in which both the plate-like component 2 that faces the sun and that serves as a front cover plate and the component 2′ that is turned away from the sun and that serves as a rear cover plate consist of a plate glass pane.

In one embodiment of the invention, it can be provided that the surface 3 and/or 3′ before assembly has a layer or several layers with a light-emitting, photovoltaic or electrochromatic function or a combination of several of the above-mentioned functions.

The modules that are shown in FIGS. 4 and 5 can also be designed as described below:

For a photovoltaic module, which is constructed as shown in FIGS. 5, 6 is a photovoltaic element, and 5, 5′ are given the composite layers of plastic, possibly of silicone-based plastic. Component 2 is a surface-treated plate glass pane, which is provided on its side 3 by means of the surface treatment with a layer with an adjusted index of refraction, barrier action for Na⁺, and enhanced adhesion. The incident-light-side surface 7 of the component 2 can have reduced reflection properties for light in the visible spectral range. The incident-light-side surface 7 can also have enhanced reflection behavior for IR radiation starting from 1,100 nm in order to reduce the heating of the module when incident light hits it (output decreases at high temperature). 2′ is a plate that is made of a material that is different from glass, e.g., Al (light and reflective) or plastic.

The above-described module 1 can also be designed as a photovoltaic module, described as follows:

The photovoltaic module has the previously-described design, whereby the component 2′ is designed as a plate glass pane, which has increased reflection by means of treatment of the surface 3′. For this purpose, an inorganic solid is used.

In a photovoltaic module with the design according to FIG. 4, the surface 3′ has a photovoltaic layer. A bonding layer 4 consists of plastic, optionally silicone-based plastic. Component 2 is a surface-treated plate glass pane, which is provided by means of the surface treatment on its side 3 with a layer with an adjusted index of refraction, barrier action for Na⁺, and enhanced adhesion. The incident-light-side surface 7 of the component 2 can have reduced reflection properties for light in the visible spectral range. The incident-light-side surface 7 can also have enhanced reflection behavior for IR radiation in order to reduce the heating of the photovoltaic module when incident light hits it (output decreases at high temperature).

An OLED module with the design according to FIG. 4, in which the surface 3′ is coated with an organic light-emitting diode (organic light-emitting diode, OLED), is possible. A bonding layer 4 that is made of plastic optionally consists of silicone-based plastic. A surface-treated plate glass pane 2 is provided by means of the surface treatment on its side 3 with a layer with an adjusted index of refraction and enhanced adhesion.

An OLED module with a design according to FIG. 5, in which the component 6 is coated with an organic light-emitting diode (OLED), is also considered. The films 5, 5′ are bonding layers that are made of plastic, optionally silicone-based plastic. The component 2 is a surface-treated plate glass pane, which is provided on its side 3 by means of surface treatment with a layer with an adjusted index of refraction and enhanced adhesion.

The design of a module according to the invention in the embodiment as a photovoltaic module is shown by way of example in FIG. 6, whereby the distances between the components are not given in practice and are shown only for reasons of drafting. The photovoltaic module has a photovoltaic element 15, on which a silicon-nitride layer 16, on which a film 14 is placed, is applied (on the incident light side). Outside on the film 14, a thermally hardened plate glass pane 11 that is made of soda-lime glass, in particular in the form of tempered safety glass (“TSG”), is arranged as a front-side cover. The outer surface of the glass pane 11 is designed to reduce reflection. Outside of the rear contact 17 of the photovoltaic element 16, a film 18, which serves to reflect light, is applied. On the rear side of the photovoltaic module, in the example shown, a pane 19, e.g., that is made of soda-lime glass, is provided as a rear-side cover (rear-side lamination), which pane can carry a layer 20 that enhances the reflection properties of the pane 19. The cover 19 can consist of glass, plastic or metal, e.g., aluminum. This layer 20 can be obtained by soda-lime glass being treated with potassium-water glass, to which a white, inorganic dye (e.g., zinc oxide) is added.

The adjusting of the (optical) properties between the pane that is made of soda-lime glass and the plastic layer is advantageous by a layer being formed by means of the surface treatment of the pane, a layer whose index of refraction has a value between the index of refraction of the glass and the index of refraction of the plastic layer.

The film 14 and optionally also the film 18 serve as embedding material and are, for example, a silicone-based plastic, such as, e.g., a thermoplastically workable silicone elastomer, such as the elastomer that can be obtained under the tradename Tectosil (www.wacker.com), a silicone-based plastic, or a silicone. Instead of films as embedding material, a liquid silicone can also be used as embedding material. In comparison to EVA or PVB, the silicone-based embedding materials or shell materials produce a lower index of refraction than the soda-lime glass, which has proven to be of value in photovoltaic elements. When assembling soda-lime glass as a cover 11 and a film 14 that is made of silicone elastomer (e.g., Tectosil), it is advantageous, on the one hand, to adapt the difference to the optical properties (indices of refraction) and to produce a barrier against drifting elements, in particular positive sodium ions and other light ions from the glass (cover 11) in the film 14 (Tectosil, silicone), since ions, such as sodium ions, negatively influence the optical behavior at the interface (which increases optical reflection). Also, the long-term stability (electrical and mechanical stability) of the glass/film (encapsulating) interface of the photovoltaic module could be adversely affected.

This can be done by using correspondingly treated glass, for example soda-lime glass, which has been treated as follows:

Plate glass, which can be used within the framework of the invention as the front-side cover 11 that faces the light, can be obtained as follows:

First, the glass, preferably plate glass that is made of soda-lime glass, for example in a chamber, is sprayed with a water glass-atomized spray. In particular, an aqueous solution of potassium-water glass is used. Before spraying, the glass can be preheated to 30° C., so that water from the air does not precipitate on the glass.

Before the pretreatment, the glass is washed in the hot state and flushed with regenerated water.

Advantageously, the glass surface is conditioned before the hardening and before the spraying of the potassium-water glass mixture so that the surface of the glass is hydrophilic. This is of advantageous importance for the homogeneity of the water glass application on the glass surface (good wetting of the glass surface by the solution of potassium-water glass). After the solution of potassium-water glass is applied and after the coating dries (i.e., after the reaction), unbonded potassium can be washed out with water at room temperature (or with acetic acid) in order to avoid the efflorescing of the surface because of the reaction of potassium oxide with carbon dioxide of the air.

First of all, the atomized spray contains a highly dilute solution of potassium-water glass in water. Preferably, the glass moves through the atomized spray, which exits from nozzles.

The atomized spray precipitates on the plate glass pane and produces a self-enclosed plate there, consisting of the solution of potassium-water glass in water. The solution of potassium-water glass forms a uniform film on the glass on one or on both sides thereof.

As a next step, the film that contains potassium-water glass is allowed to dry, whereby the potassium-water glass reacts with the glass. In a subsequent washing process, potassium that is not bonded to glass is washed out.

Subsequently, the glass, as is customary for thermal hardening, is heated and cooled, whereby the previously-bonded layer sinter-fuses, and a continuous transition from the glass core to the outer layer that is made of potassium-water glass is produced.

Another essential advantage of soda-lime glass that is treated with potassium-water glass as described is that the glass better adheres to the silicones (e.g., Tectosil film) that are used as embedding material, so that a deep connection between glass as a cover and silicone as an embedding material is provided. This deep connection between the embedding material and the glass pane 11 that is provided as a front-side cover enhances, i.a., because of the reduced reflection, the admission of light into the photovoltaic cell 15.

The thickness of the layer that is formed by surface treatment on the glass surface has a value of below 200 nm, so that a smooth surface without scattering centers for visible light is present.

Thus, (thin) glass that is treated in its optical properties and thermally hardened, i.e., refined, is obtained, which can be used for the module according to the invention in the form of a photovoltaic module.

For the surface treatment of the outer surfaces (7, 7′ in FIGS. 4 and 5) and that of the inner surfaces (3, 3′ in FIGS. 4 and 5), in principle the method that is further described above can be used.

Consideration is given to adjusting the method to the desired result (in particular changing the reflection properties and changing the indices of refraction) by selection of the method parameters and by setting the treatment means.

Below, an embodiment of the invention is reproduced:

### EXAMPLE

In this example, clear glass that is 2.1 mm thick with dimensions of 550×360 mm is treated with an aqueous solution of potassium-water glass.

The procedure is as follows:

The glass is washed in a washing machine with hot water that is approximately 40° C. Subsequently, the glass surface is treated with a flame. Then, a glass surface is treated with an aqueous potassium-water glass solution. After the treatment, there is a waiting period until the treatment material has reacted with the glass in the area of its surface, which takes approximately 10 to 15 minutes.

The solution that is used for treatment had the following composition: 96-97% by weight of water and 3-4% by weight of proportions of solids (SiO₂, K₂O, . . . ), whereby the potassium content of the liquid is less than 1% by weight, and in the treatment material, a proportion of solid of 3.4% by weight is present.

Subsequently, the glass is again flushed with hot water of 40° C.

Subsequently, the glass is subjected to thermal hardening, whereby a usual procedure is followed.

After this, a photovoltaic module is prepared with the treated glass with the following design:
Face-plate made from treated glass as previously described, whereby the treated glass surface points toward the interior of the module (embedding material),
Tectosil embedding film,
Photovoltaic cell,
Tectosil embedding film,
2 mm heat-treated back glass.

As a reference module, an equally good module was designed as previously described but with untreated face-plate.

By the measurement of the electrical output in the case of irradiation with a light source of the two modular structures, an increment of 1% could be determined in the module with treated face-plate.

In summary, an embodiment of the invention can be described as follows.

A module, for example a photovoltaic module, comprises, i.a., as a front cover that faces the incident light, a glass plate 11, a component (photovoltaic element) 15, and a plastic layer 14 that is provided as embedding material, whereby the glass plate 11 is treated on the surface on the side that faces the plastic layer 14 such that the index of refraction of the layer that is produced by the surface treatment has a value between the index of refraction of the glass of the cover 11 and the index of refraction of the plastic material of the layer 14.

1. Module (1) with two components (2, 2′), of which at least one is translucent and between which a layer that is made of plastic is provided, characterized in that the surface (3, 3′), which faces the layer that is made of plastic, of at least one translucent component (2, 2′) is designed to enhance the transfer of light into the layer that is made of plastic.

2. Module according to claim 1, wherein at least one of the components (2, 2′) is a plate glass pane.

3. Module according to claim 1, wherein the layer that is made of plastic is a layer that is made of casting resin.

4. Module according to claim 1, wherein the layer that is made of plastic comprises at least one film (4, 5, 5′) that is made of plastic.

5. Module according to claim 4, wherein another component (6) is provided between two films (5, 5′) that are made of plastic.

6. Module according to claim 1, wherein the surface (3, 3′), which faces the layer that is made of plastic, of at least one translucent component (2, 2′) has a layer that increases the transmission of light.

7. Module according to claim 6, wherein the index of refraction in the layer that increases the transmission of light has a value between the index of refraction of the component (2, 2′) and the index of refraction of the layer (4, 5, 5′) that is made of plastic.

8. Module according to claim 1, wherein the incident-light-side surface (7) of the front cover plate is designed to reduce the reflection in the wavelength range of visible light.

9. Module according to claim 1, wherein the incident-light-side surface (7) and/or the surface (3) of the front cover plate that faces the layer that is made of plastic has enhanced reflection behavior for infrared light.

10. Module according to claim 1, wherein the layer that is made of plastic consists of silicone-based plastic.

11. Module according to claim 1, wherein the layer that is made of plastic comprises one or two films (5, 5′) that are made of silicone-based plastic.

12. Module according to claim 1, wherein the surface (3′) has a layer or several layers with a light-emitting, photovoltaic or electrochromatic function or a combination of several of the above-mentioned functions.

13. Module according to claim 12, wherein the component (6) is a photovoltaic element, and wherein the component (2) that faces the sun and that serves as a front cover plate is a plate glass pane, while the component (2′) that is turned away from the sun and that serves as a rear cover plate consists of a material that is different from glass, in particular a metal material or plastic.

14. Module according to claim 12, wherein the component (6) is a photovoltaic element and wherein both the plate-like component (2) that faces the sun and that serves as a front cover plate and the component (2′) that is turned away from the sun and that serves as a rear cover plate consist of a plate glass pane.

15. Photovoltaic module comprising at least one photovoltaic element (15) and front and rear covers (11, 19), whereby the front cover that faces toward the incident light is a glass plate (11) and embedding material (14) that is made of plastic is arranged between the glass plate (11) and the photovoltaic element (15), and whereby the photovoltaic element (15) is arranged between the embedding material (14) and the rear cover (19), wherein at least one glass plate (11) that is arranged on the incident light side is a (plate) glass pane, which has reflection behavior that is reduced by treatment.

16. Photovoltaic module according to claim 15, wherein between the glass plate (11) on the incident light side and the photovoltaic element (15), a film (14) that is made of silicone-based plastic is arranged as embedding material.

17. Photovoltaic module according to claim 15, wherein the treated glass plate (11) is a particularly hardened plate glass pane that is made of soda-lime glass.

18. Photovoltaic module according to claim 15, wherein a film (18) and/or a glass pane (19) with a reflection behavior, which is greater than that of the incident-light-side glass plate, is arranged on the rear side of the photovoltaic element (15) that is opposite to the incident light side.

19. Photovoltaic module according to claim 15, wherein the index of refraction in the layer (13) that enhances the transmission of light has a value between the index of refraction of the glass of the plate (11) and the plastic material of the film (14).

20. Method for the production of a module according to claim 1, in which a film (4) is arranged between two flat or plate-like components (2, 2′), of which at least the first component (2) is designed as a plate glass pane, or a plate-like or film-like component (6) is arranged between two films (5, 5′), whereby the components (2, 2′) as well as the film (4) that is introduced in-between or the stack that is made of the two films (5, 5′) and the component (6) are connected to one another by lamination or vacuum encapsulation, wherein before the assembly of the module, the film-side surface (3) is subjected to a surface treatment or, if both components (2, 2′) are designed as plate glass panes, a surface treatment is optionally performed on both film-side surfaces (3, 3′).

21. Method for the production of a module according to claim 1, in which a film (4) is arranged between two flat or plate-like components (2, 2′), of which at least the first component (2) is designed as a plate glass pane, or a plate-like or film-like component (6) is arranged between two films (5, 5′), whereby the components (2, 2′) as well as the film (4) that is introduced in-between or the stack that is made of the two films (5, 5′) and the component (6) are connected to one another by lamination or vacuum encapsulation, wherein before the assembly of the module, the film-side surface (3) is subjected to a surface treatment, or, if both components (2, 2′) are designed as plate glass panes, optionally also both film-side surfaces (3, 3′) are subjected to a surface treatment, and wherein during the course of the lamination process, the film material goes into a connection with the glass and with the layer formed on the surface (3) or the layers formed on the surfaces (3, 3′) by means of the surface treatment.

22. Method for the production of a module according to claim 1, in which a film (4) is arranged between two flat or plate-like components (2, 2′), of which at least the first component (2) is designed as a plate glass pane, or a plate-like or film-like component (6) is arranged between two films (5, 5′), whereby the components (2, 2′) as well as the film (4) that is introduced in-between or the stack that is made of the two films (5, 5′) and the component (6) are connected to one another by lamination or vacuum encapsulation, wherein before the assembly of the module, the film-side surface (3) is subjected to a surface treatment, or, if both components (2, 2′) are designed as plate glass panes, optionally also both film-side surfaces (3, 3′) are subjected to a surface treatment, whereby an enhanced adhesion is achieved between a plate glass pane or plate glass panes and film material.

23. Method for the production of a module according to claim 1, in which a film (4) is arranged between two flat or plate-like components (2, 2′), of which at least the first component (2) is designed as a plate glass pane, or a plate-like or film-like component (6) is arranged between two films (5, 5′), whereby the components (2, 2′) as well as the film (4) that is introduced in-between or the stack that is made of the two films (5, 5′) and the component (6) are connected to one another by lamination or vacuum encapsulation, wherein before the assembly of the module, the film-side surface (3) is subjected to a surface treatment, or, if both components (2, 2′) are designed as plate glass panes, optionally also both film-side surfaces (3, 3′) are subjected to a surface treatment, whereby a reduced transfer of sodium ions from the glass into the film material is achieved.

24. Method for the production of a module according to claim 1, in which a film (4) is arranged between two flat or plate-like components (2, 2′), of which at least the first component (2) is designed as a plate glass pane, or a plate-like or film-like component (6) is arranged between two films (5, 5′), whereby the components (2, 2′) as well as the film (4) that is introduced in-between or the stack that is made of the two films (5, 5′) and the component (6) are connected to one another by lamination or vacuum encapsulation, wherein before the assembly of the module, the film-side surface (3) is subjected to a surface treatment, or, if both components (2, 2′) are designed as plate glass panes, optionally also both film-side surfaces (3, 3′) are subjected to a surface treatment, whereby an enhanced transmission of light in the visible spectral range through the at least one plate glass pane into the film is achieved by adjusting the relative indices of refraction.

25. Method for the production of a module according to claim 1, in which a film (4) is arranged between two flat or plate-like components (2, 2′), of which at least the first component (2) is designed as a plate glass pane, or a plate-like or film-like component (6) is arranged between two films (5, 5′), whereby the components (2, 2′) as well as the film (4) that is introduced in-between or the stack that is made of the two films (5, 5′) and the component (6) are connected to one another by lamination or vacuum encapsulation, wherein before the assembly of the module, the film-side surface (3) is subjected to a surface treatment, or, if both components (2, 2′) are designed as plate glass panes, optionally also both film-side surfaces (3, 3′) are subjected to a surface treatment with water glass, in particular with potassium-water glass.

26. Method for the production of a module according to claim 1, in which a film (4) is arranged between two flat or plate-like components (2, 2′), of which at least the first component (2) is designed as a plate glass pane, or a plate-like or film-like component (6) is arranged between two films (5, 5′), whereby the components (2, 2′) as well as the film (4) that is introduced in-between or the stack that is made of the two films (5, 5′) and the component (6) are connected to one another by lamination or vacuum encapsulation, wherein before the assembly of the module, the film-side surface (3) is subjected to a surface treatment, or, if both components (2, 2′) are designed as plate glass panes, optionally also both film-side surfaces (3, 3′) are subjected to a surface treatment, whereby the surface treatment comprises the following method steps:
The object that is made of glass, preferably a plate glass pane, in particular a plate glass pane that is made of soda-lime glass, is cleaned,
An aqueous solution of potassium-water glass is applied in a continuous layer to the object by the object being sprayed with an aqueous solution of potassium-water glass,
The layer that is applied on the object is allowed to dry, whereby the potassium-water glass reacts with the surface of the object,
Unbonded potassium is washed out from the applied layer with water, and
The object is heated for heat treatment and cooled again to room temperature for thermal hardening.

27. Method according to claim 20, wherein the treatment of the surface that is carried out before assembly is performed with potassium-water glass.

28. Method according to claim 20, wherein in the treatment of the surface (3) before assembly, a solution is used to which at least a dye, in particular an inorganic dye, is added.

29. Method according to claim 20, wherein in the treatment of the surface (3) before assembly, a solution is used to which at least one fluorescent substance is added.

30. Method according to claim 20, wherein in the treatment of the surface (3) before assembly, a solution is used that is added to at least one substance that ensures conductivity.

31. Method according to claim 20, wherein for the treatment of the surface (3′) before assembly, a solution is used to which at least a dye, in particular an inorganic dye, is added.

32. Method according to claim 20, wherein for the treatment of the surface (3′) before assembly, a solution is used to which at least one fluorescent substance is added.

33. Method according to claim 20, wherein for the treatment of the surface (3′) before assembly, a solution is used to which at least one substance that ensures conductivity is added.

34. Method according to claim 20, wherein in which for the treatment of the surface (3′) of the rear cover before assembly, a solution is used to which a dye is added and that imparts enhanced reflection behavior to the rear cover plate.

35. Method according to claim 20, wherein the incident-light-side surface (7) of the front cover plate has reduced reflection properties in the wavelength range of visible light.

36. Method according to claim 20, wherein the incident-light-side surface (7) and/or the surface (3), which faces the laminating film, of the front cover plate has enhanced reflection behavior for infrared light.

37. Method according to claim 20, wherein the film (4) consists of silicone-based plastic, or optionally both films (5, 5′) consist of silicone-based plastic.
